(19) United States
(12) Patent Application Publication
(10) Pub. No.: US 2010/0141237 A1
(43) Pub. Date: Jun. 10, 2010

(54) Active Sensor, Use Thereof and Method for Compensating Amplitude Fluctuations in the Output Current Signal of an Active Sensor

(75) Inventors: Timo Dietz, Hochheim am Main (DE); Wolfgang Jöckel, Obertshausen (DE); Ralf Klausen, Frankfurt am Main (DE)

Correspondence Address: RATNERPRESTIA, P.O. BOX 980, VALLEY FORGE, PA, 19482, US

(73) Assignee: Continental Teves AG & Co. oHG, Frankfurt (DE)

(21) Appl. No.: 12/515,844

(22) PCT Filed: Nov. 27, 2007
(86) PCT No.: PCT/EP2007/062908

§ 371 Date: Jan. 19, 2010

(30) Foreign Application Priority Data
Nov. 28, 2006 (DE) 102006056452.9
Jun. 9, 2007 (DE) 102007026788.8

(51) Int. Cl. G01R 19/00

(52) U.S. Cl. 324/76.11

(57) ABSTRACT

An active sensor consisting of a measuring module and an interface module comprising at least one first current source, an input line and an output line, wherein the active sensor is supplied with energy via these two lines and the first current source is connected on the output side to the output line and the interface module generates the output signals of the active sensor in the form of current signals, wherein the interface module comprises a current sensing device which senses the load current of the measuring module, and a compensating device which can generate, on an output path connected to the output line, a first compensating current for compensating for amplitude fluctuations in the output current signals in dependence on the sensed load current of the measuring module. Also described is a method for compensating for amplitude fluctuations in the output current signals of an active sensor.

### CROSS REFERENCE TO RELATED APPLICATIONS

This application is the U.S. national phase application of PCT International Application No. PCT/EP2007/062908, filed Nov. 27, 2007, which claims priority to German Patent Application No. DE102006056452.9, filed Nov. 28, 2006 and German Patent Application No. DE102007026788.8, filed Jun. 9, 2007, the contents of such applications being incorporated by reference herein.

### BACKGROUND OF THE INVENTION

1. Field of the Invention

The invention relates to an active sensor and the use of the active sensor, particularly as wheel speed sensor, in motor vehicles.

2. Description of the Related Art

WO 98/08711 describes an active rotational-speed sensor which is connected to an electronic control unit via two lines and is supplied with energy and transmits the output signals via these two lines. The active sensor has a signal processing circuit and a current interface. In this arrangement, the adjustment of defined amplitudes of the output signals is achieved by means of adequate parameterization and calibration of the active sensor which is relatively costly, taking into consideration external influences or disturbances and the aging process.

In DE 199 06 981 A1, an integrated calibrating and measuring device for measuring sensors, which device can carry out a calibration of the measuring sensor by means of a data and control unit and a digital/analog converter is proposed. However, the proposed circuit is relatively complex and provides at the output side voltage signals which, according to experience, are not very suitable for signal transmission. In addition, this proposed circuit cannot compensate for amplitude fluctuations in the signal processing output signals, caused, for example, by aging or temperature influences.

### SUMMARY OF THE INVENTION

An object of the present invention consists in proposing an active sensor comprising a current interface for generating defined and especially compensated output current signal amplitudes, and to a method for compensating for amplitude fluctuations in the output current signals and, respectively, for adjusting defined output current signal amplitudes.

The invention relates to the concept of proposing an active sensor consisting of a measuring module and an interface module which comprises a current sensing device and at least one compensating device, wherein the current sensing device senses the load current of the measuring module and the compensating device can generate, in dependence on at least the sensed load current of the measuring module, at least one first compensating current which can be superimposed on the as yet uncorrected output current signal of the active sensor.

By superimposing the compensating current on the output current signal, an output current of defined amplitude can be set independently of essentially external influences, for example due to the temperature or aging influences. Unwanted amplitude fluctuations or changes in the amplitudes of the output current signal of the active sensor can thus be avoided. This makes it possible to guarantee that the amplitude-coded output information of the active sensor can be decoded correctly by the respective receiver, for example the electronic control unit of a motor vehicle control system. This is particularly relevant when using the sensor in safety-critical systems such as, for example, a motor vehicle control system. Amplitude fluctuations of the output current signal no longer need to be compensated for almost completely or with relatively great expenditure by means of a relatively elaborate calibration as has previously been common practice. Neither do production inaccuracies of electronic components need to be corrected, especially by trimming, due to the adjustment of a defined output signal amplitude according to aspects of the invention.

The measuring module suitably comprises at least one sensor element and a signal processing circuit. The first compensating current of the compensating device is preferably generated in dependence on the sensed load current of the measuring module and of the current generated by the first current source.

The first compensating current and/or other compensating currents of the compensating device are preferably connectable or disconnectable and/or controllable. As a result, an amplitude-coded information transmission can be carried out by means of the sensor output signals.

It is suitable that the compensating device is connected on the input side to the input line in a first node, the first current source is connected on the output side to the output line in a second node and the first output path of the compensating device is connected to the second node as a result of which the first compensating current of the compensating device can be generated additionally in dependence on the sensor input current. Due to the above interconnection, in particular, the output current of the measuring module, the output current of the first current source and the first output current of the compensating device are superimposed to form an output current signal of the active sensor.

The current sensing device, on the output side, and the compensating device, are preferably jointly connected to the input of the first current source by means of a second output path. The current to be provided at the second output path of the compensating device is the result of the output current of the current sensing device and the current through the first current source. The compensating device generates at least the first compensating current especially in dependence on this current to be provided on the second output path and especially preferably in dependence on the input current of the active sensor.

The input of the current sensing device is suitably connected to the input line and/or output line between the measuring module and the first or the second node. By this means, the current sensing device is able to sense the load current of the measuring module in a relatively simple manner.

The measuring module is preferably connected in each case to the extension of the first and second line and is essentially supplied with energy via these two lines.

The current sensing device preferably has at least one sense FET and/or sense amplifier, as a result of which the output current of the current sensing device is less by an essentially defined ratio than the load current of the measuring module. By using at least one sense FET or sense amplifier, the energy consumption of the current sensing device itself is kept relatively low so that this results in a relatively small, essentially calculable systematic measurement deviation. As an alternative, the current sensing device preferably exhibits a shunt.

It is suitable that the current sensing device provides at its output at least one current which is different, particularly less, by a defined first scaling factor than the current sensed at its input.

The first compensating current generated by the compensating device preferably has an amplitude which is changed by a defined second scaling factor, especially a greater amplitude than the current provided at the second output path of the compensating device. It has been found that by means of the at least one scaling factor of the current sensing device and of the compensating device, an at least first compensating current can be set in a relatively simple manner, which current, in particular, is suitable for adjusting or correcting the output current signal of the active sensor to at least one defined amplitude value. In an especially preferred manner, the first scaling factor of the current sensing device and the second scaling factor of the compensating device are essentially equally large.

It is preferred that the compensating device can generate, as an alternative to the first compensating current at the first output path or additionally at at least one additional output path connected to the second node, at least one second compensating current which differs from the first compensating current. In this arrangement, the compensating currents are different by a defined, in each case mutually different scaling factor from the current provided at the second output path of the compensating device. In particular, the compensating currents are greater by in each case a mutually different scaling factor than the current provided at the second output path. In this arrangement, it is possible to switch between these compensating currents as a result of which the output current signal can be adjusted or corrected to different amplitudes in a relatively simple manner.

The current sensing device can suitably provide at its output at least one first and one second current, which currents are different, particularly less, by a defined, in each case mutually different scaling factor, than the current sensed at the input. In this arrangement, it is possible to switch between these currents on the output side.

The interface module preferably also additionally has at least one second connectable and/or controllable current source which is connected to the first node on the input side and to the second node on the output side. By this means, at least two or a multiplicity of defined amplitude values of the output current signal can especially be adjusted or corrected.

It is suitable that the interface module additionally has at least one first current driver element capable of being switched on, which is connected to the first node on the input side and provides on the output side a first current at the input of an additional current source. The output of this current source is connected to the second node, wherein the current driver element can additionally generate on the output side a second current which is different by a defined scaling factor with respect to the first current, at at least one additional output path connected to the second node. By means of such a current driver element, an alternative or additional amplitude coding of the output current signal can be carried out. The current driver element can also be considered, and correspondingly designed, as an additional compensating device capable of being switched on which is not connected to the current sensing device and the output currents of which are correspondingly independent of the sensed load current of the measuring module or the output current of the current sensing device, respectively.

The at least one current source preferably exhibits a preset, defined current value. In particular, this current value is corrected by means of a control loop. All current sources of the interface module exhibit in a particularly preferred manner an essentially identical preset, especially preferably corrected current value. By means of such a measure, the interface module becomes essentially insensitive to external influences and internal changes of the components and can adjust even more precisely defined amplitudes of the output current signal.

The compensating device suitably exhibits one or more electronic current balancing circuit/s.

It is preferred that the measuring module and the interface module, or the signal processing circuit and the interface module are constructed as an integrated circuit, especially on a chip.

The current sensing device, the compensating device and especially at least one current driver element and/or at least one additional connectable and/or controllable current source are preferably connected to at least one signal output of the measuring module on the input side and are controlled by the measuring module, especially with regard to a switching-over of the scaling factors. By this means, the output information of the measuring module can be provided in a relatively simple manner by modulation of the output current signals, by means of the interface module and, in this context, by driving the individual circuit elements, at the output of the active sensor.

It is suitable that as part of the method, the compensating device can generate at least one additional and/or alternative compensating current, wherein it is possible to switch between these compensating currents in dependence on at least one output signal of the measuring module.

The interface module preferably has with regard to the method at least one additional current source and/or at least one current driver element which generates at least one output current which can be connected or switched in dependence on at least one output signal of the measuring module and which is/are superimposed on the output current of the active sensor.

The invention also relates to the use of the active sensor, especially as wheel speed sensor, in motor vehicles.

The sensor according to aspects of the invention and the method according to aspects of the invention are provided for use in the fields of motor vehicle technology, automation and control technology. In particular, the use of the sensor according to aspects of the invention and of the method in wheel speed sensors is provided.

These and other aspects of the invention are illustrated in detail by way of the embodiments and are described with respect to the embodiments in the following, making reference to the Figures.

### BRIEF DESCRIPTION OF THE DRAWINGS

The invention is best understood from the following detailed description when read in connection with the accompanying drawing. Included in the drawing are the following figures:

FIG. 1 shows an exemplary embodiment of the basic operation of the interface module,

FIG. 2 shows an exemplary active sensor for adjusting two defined amplitudes of the output current signal, wherein the current sensing device and the compensating device can in each case generate two switchable output currents,

FIG. 3 shows an exemplary embodiment of the active sensor with an additional current driver element, and

FIG. 4 shows an exemplary active sensor with an illustrated drive of the current sensing and compensating device by the signal processing circuit of the measuring module.

### DETAILED DESCRIPTION OF THE PREFERRED EMBODIMENTS

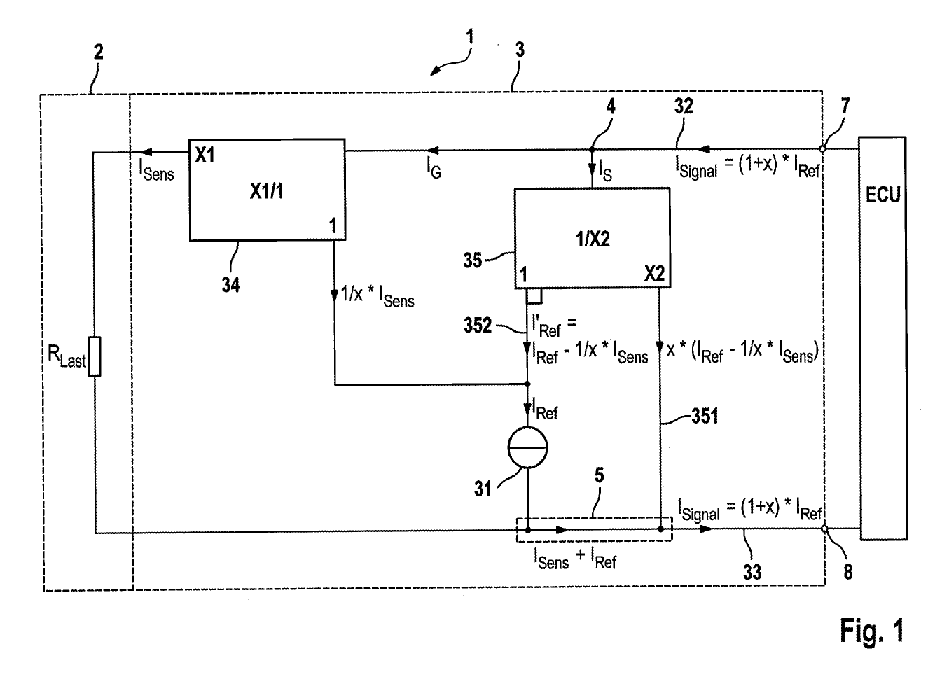

The exemplary, active sensor shown in FIG. 1 is used for illustrating the basic operation. The active sensor 1 is connected to the electronic control unit of a motor vehicle control system ECU by means of a two-wire line and is supplied with energy via these two lines. In addition, all information is also exchanged between the active sensor 1 and the ECU via these two lines. This particularly refers to the output information of the active sensor 1. These two connecting lines are connected to the active sensor 1 by means of terminals 7 and 8. As an extension of these two connecting lines and connected to terminals 7 and 8 on the sensor side, interface module 3 has an input line 32 and an output line 33. The measuring module 2, the entire load impedance of which is combined and illustrated by the resistance R_{load}, is connected to these two lines on the sensor side. At node 4 of the input line 32, the inputs of the current sensing device 34 and of the compensating device 35 are connected. The current sensing device 34 senses the load current Iₛₑₙₛₑ by means of the measuring module 2 and provides this current, reduced by a defined factor X1, at its output. The current source 31 drives a defined current in the node 5 of the output line 33 and is connected on the input side to the output of the current sensing module 34 and, via the second output path 352, to the compensating device 35. In this arrangement, the compensating device 35 provides at the second output path 352 a current which results from the difference of the current I_{ref} through the current source 31 and the output current of the current sensing device 34. In dependence on this compensating current provided at the second output path 352, the compensating device 35 generates at its first output path 351, connected to the node 5, a current amplified by a defined factor X2 which corresponds to the factor X1, for compensating for the as yet uncorrected current output signal of the active sensor 1.

The exemplary active sensor 1 thus corrects the output current signal I_{signal} so that a constant signal current is set independently of the present current consumption of the measuring module 2. I_{signal} is essentially dependent only on a reference current I_{ref} of the current source 31. For example, the following holds true:

I_{signal}=y*I_{ref}=(1+x)*I_{ref} (1)

where:x=x1=x2

For this purpose, a current source 31 which acts as reference current source provides the temperature-independent current I_{ref}. The total current of the measuring current for the current sensing by means of the current sensing device 34 and basic current consumption of the measuring module 2 is obtained as:

I_{G}=(1+1/x)* Iₛₑₙₛₑ (2)

The sense current, reduced by the current sensing device 34, is now subtracted from the current source 31 which results in a new reference current

I_{ref}=I_{ref}−1/x*Iₛₑₙₛₑ (3)

which is provided by the compensating device 35 at the second output path 352. This compensating current is amplified by the factor X2 by the compensating device 35 and generated at the first output path 351. According to the example, the compensating device 35 has a simple current balancing arrangement which is fed by the input line 32 or the energy supply of the active sensor 1. The input current I_{S} of the compensating device 35 is then obtained as:

I_{S}=(1+x)*I′_{ref}=(1+x)*(I_{ref}−1/x*Iₛₑₙₛₑ) (4)

The signal current I_{signal}, that is to say the total current consumption of the active sensor 1 is the sum of I_{G} and I_{S}, from which it follows that:

I_{signal}=I_{G}+I_{S}=(1+1/x)*Iₛₑₙₛₑ+(1+x)*(I_{ref}−1/x*Iₛₑₙₛₑ) (5)

[symbol]

I_{signal}=Iₛₑₙₛₑ+Iₛₑₙₛₑ/X+(1+x)*I_{ref}−Iₛₑₙₛₑ/X−Iₛₑₙₛₑ

[symbol]

I_{signal}=(1+x)*I_{ref}

The signal current or the output current signal of the active sensor 1 is thus independent of the current consumption of the remaining circuits or of the measuring module 2, respectively, and essentially only dependent on the reference current I_{ref} of the current source 31. In the case of integrated circuits, the scaling factors X1=X2 are specified by the component ratios which can be implemented independently of process fluctuations.

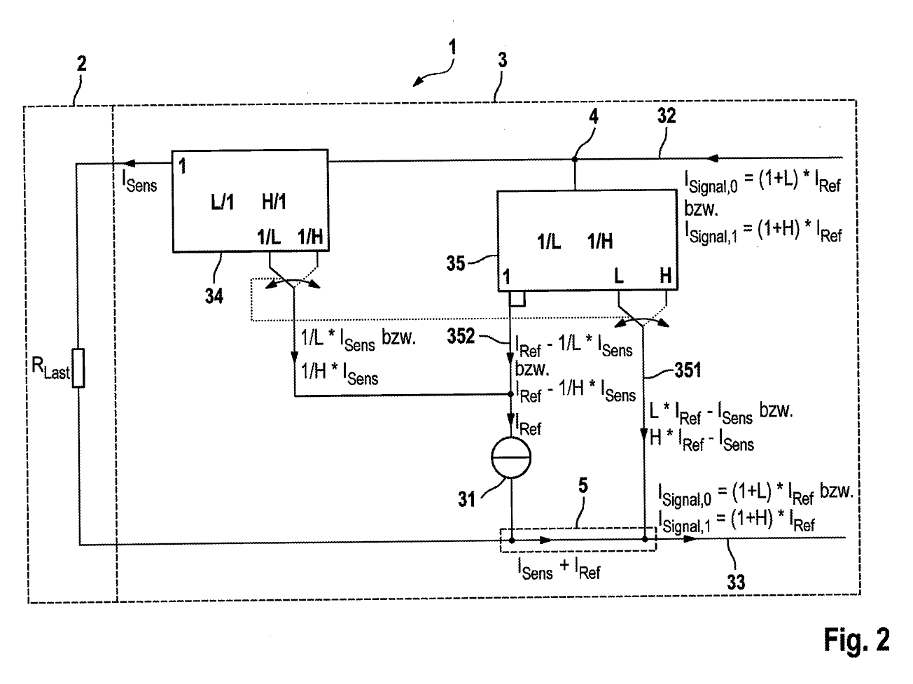

FIG. 2 illustrates an exemplary embodiment of the active sensor 1 for generating two different amplitudes of the output current signal I_{signal}. Starting with the active sensor 1 shown in FIG. 1, the current sensing device 34 in this arrangement has at its output, and the compensating device 35 has at its first output path 351, a change-over switch or is constructed to be switchable, respectively. In this arrangement, the current sensing device 34 is constructed in such a manner that it can provide two alternative currents which in each case have a current amplitude reduced by two defined scaling factors L and H with respect to the sensed load current Iₛₑₙₛₑ of the measuring module 2. Correspondingly, the compensating device 35 generates at the first output path 351 two alternative compensating currents which are amplified by two defined scaling factors L and H with respect to the current provided at their second output path 352 or, respectively, have an amplitude increased by these scaling factors.

For the logical “0” level corresponding to the switch positions with continuous line, the current sensing device 34 thus provides a sense current Iₛₑₙₛₑ, reduced by the scaling factor L to 1, which is subtracted from I_{ref}. This reduced reference current I′_{ref} is amplified by the scaling factor L by the compensating device 35. The total current consumption of the active sensor 1 is therefore obtained as:

I_{signal,0}=(1+L)*I_{ref} (6)

For the logical “1” level corresponding to the switch position with dashed line, Iₛₑₙₛₑ is reduced by the scaling factor H by the current sensing device 34 and I′_{ref} is amplified by the scaling factor H by the compensating device 35. The total current of the active sensor 1 is then obtained as:

I_{signal,1}=(1+H)*I_{ref} (7)

The amplitude of the output signal current I_{signal} for logical “0” and “1” levels can thus be adjusted by the scaling factors L and H and the reference current I_{ref} of the current source 31.

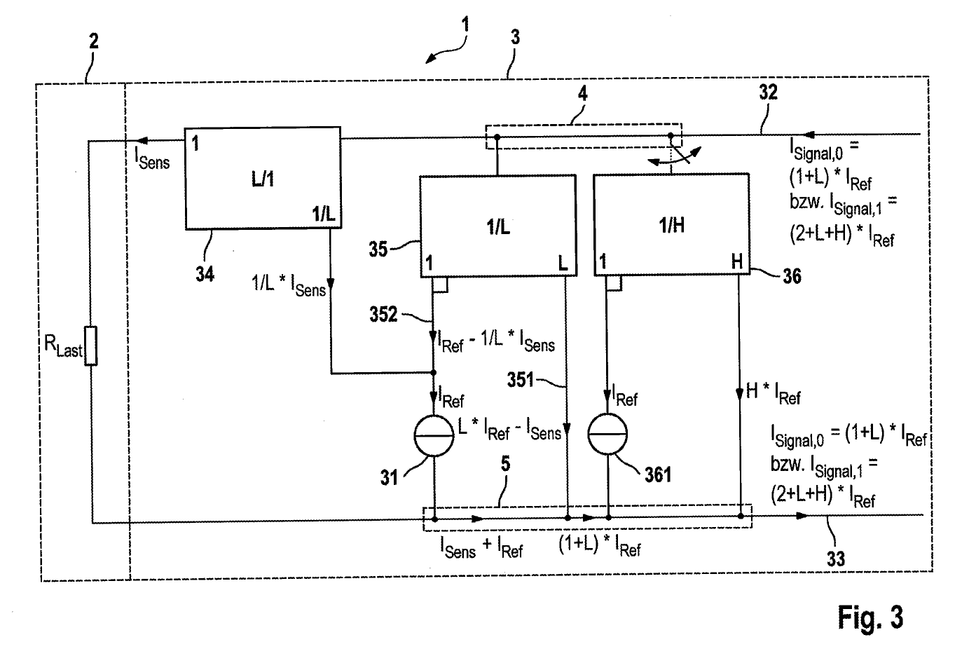

FIG. 3 shows an alternative exemplary embodiment of the active sensor 1 for generating two different amplitudes of the output current signal I_{signal}. This exemplary embodiment extends the active sensor 1 shown in FIG. 1 by a connectable current driver element 36 which is connected to the first node 4 of the input line 32 on the input side and provides on the output side a first current at the input of an additional current source 361, the output of which is connected to the second node 5 of the output line 33. In this arrangement, the current driver element 36 can generate on the output side an additional second current H*I_{ref} at an additional output path, connected to the node 5, which current is amplified by the defined scaling factor H with respect to the first current provided at the input of the current source 361. The current driver element 36 has, for example, a current balancing circuit. By adding or connecting the current driver element 36, the amplitude corresponding to a logical “1” of the output current signal I_{signal} is generated. The current driver element 36 can also be largely understood to be a connectable compensating device which is independent of the current sensing device 34, and can be correspondingly designed. The compensating device 35, for example, is continuously active. For the logical “0” level of the output current signal of the active sensor 1, the switch of the current driver element 36 is open and the current driver element 36 is thus not active. The signal current or the amplitude of the output current signal of the active sensor 1, respectively, is thus obtained as:

I_{signal,0}=(1+L)*I_{ref} (8)

For the logical “1” level, the switch of the current driver element 36 is closed, the current (1+H I_{ref}, which is generated by the current driver element 36, is added to the signal current from equation (8) in the second node 5. This results in the following total current of the active sensor 1:

I_{signal,1}=(1+L)*I_{ref}+(1+H)*I_{ref}=(2+L+H)*I_{ref} (9)

In this exemplary embodiment, too, the logical “0” and “1” levels can be adjusted with the aid of the factors L, H and I_{ref}. These levels are switched in dependence on the measuring module 2.

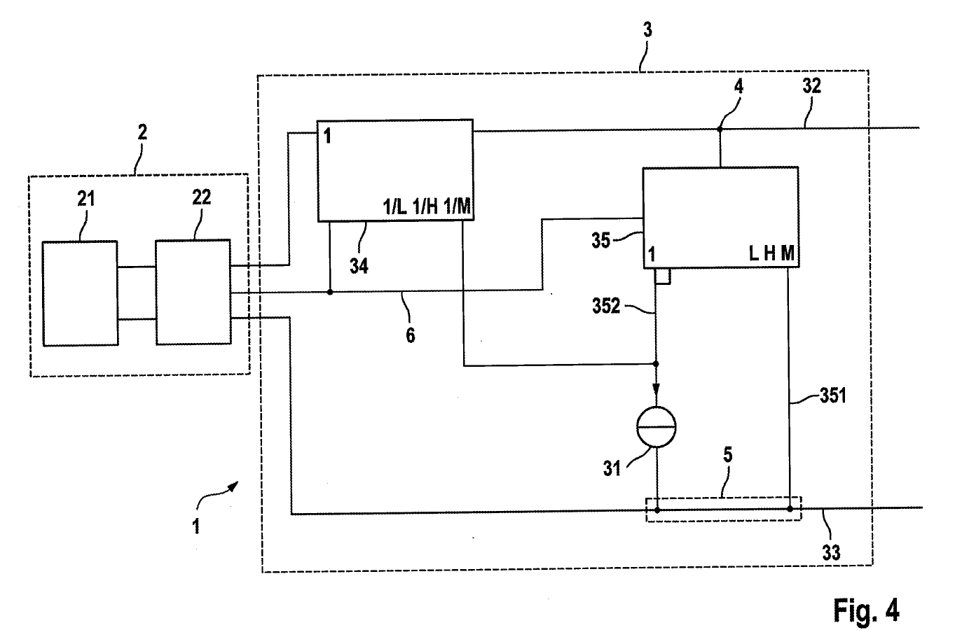

FIG. 4 illustrates an exemplary active sensor 1 with a measuring module 2 comprising a sensor element 21 and a signal processing circuit 22 and with the interface module 3. Compared with the exemplary embodiment shown in FIG. 2, this active sensor 1 has been extended. In this arrangement, the current sensing device 34 and the compensating device 35 in each case have an additional input via which they are jointly driven by the signal processing device 22 of the measuring module 2 by means of a control line 6. Via this control line 6, the switch-over of the scaling factors of the current sensing device 34 and the compensating device 35 are controlled, for example.

The signal processing device 22 thus continuously specifies which scaling factor of these two devices is “active” and thus correspondingly specifies the total amplitude of the output current signal of the active sensor 1. According to the example, three different amplitudes of the output current signal I_{signal} can be set. For this purpose, the current sensing device 34 and the compensating device 35 in each case have three different scaling factors L, H, M and alternatively generate, in accordance with the exemplary embodiments described above, now with an additional scaling factor, the corresponding three output currents. According to the example, these three different amplitudes are used for the data transmission protocol of the active sensor 1 as wheel speed sensor. In this arrangement, additional data, for the coding of which the medium amplitude is used, are transmitted between the speed pulses which are coded by the largest amplitude or the change between largest and lowest amplitude, respectively.

In an exemplary embodiment, not shown, the active sensor 1 comprises two current drive elements as a result of which it is also possible to set or generate three different amplitudes of the output current signal in a defined manner.

While preferred embodiments of the invention have been described herein, it will be understood that such embodiments are provided by way of example only. Numerous variations, changes and substitutions will occur to those skilled in the art without departing from the spirit of the invention. It is intended that the appended claims cover all such variations as fall within the spirit and scope of the invention.

1.-18. (canceled)

19. An active sensor comprising:
a measuring module and an interface module, which includes at least one first current source, an input line and an output line,
wherein the active sensor is supplied with energy via the input line and the output line and the first current source is connected on an output side to the output line and the interface module generates output signals of the active sensor in the form of current signals,
wherein the interface module includes a current sensing device which senses a load current of the measuring module, and at least one compensating device which can generate, on an output path connected to the output line, at least one first compensating current for compensating for amplitude fluctuations in the output current signals at least in dependence on the sensed load current of the measuring module.

20. The active sensor as claimed in claim 19, wherein the first compensating current is generated by the compensating device in dependence on the sensed load current of the measuring module and the current generated by the first current source.

21. The active sensor as claimed in claim 19, wherein the compensating device is connected on an input side to the input line in a first node, the first current source is connected on the output side to the output line in a second node, and the first output path of the compensating device is connected to the second node.

22. The active sensor as claimed in claim 21, wherein the compensating device and the output side of the current sensing device are jointly connected to an input of the first current source by a second output path.

23. The active sensor as claimed in claim 22, wherein an input of the current sensing device is connected to the input line, the output line, or both the input line and the output line, between the measuring module and the first node or the second node.

24. The active sensor as claimed in claim 23, wherein the current sensing device provides at least one current at its output which differs from a current sensed at its input by a defined first scaling factor.

25. The active sensor as claimed in claim 24, wherein the current sensing device provides at least one current at its output which is less than a current sensed at its input by a defined first scaling factor.

26. The active sensor as claimed in claim 24, wherein the first compensating current generated by the compensating device differs from a current provided at the second output path of the compensating device by a defined second scaling factor.

27. The active sensor as claimed in claim 26, wherein the first compensating current generated by the compensating device is greater than a current provided at the second output path of the compensating device by a defined second scaling factor.

28. The active sensor as claimed in claim 26 wherein the first scaling factor of the current sensing device and the second scaling factor of the compensating device are substantially equal.

29. The active sensor as claimed in claim 21, wherein the compensating device can generate, as an alternative to the first compensating current at the first output path or additionally at least one additional output path connected to the second node, at least one second compensating current which differs from the first compensating current, wherein these compensating currents are greater by a defined, in each case mutually different, scaling factor, than a current provided at the second output path of the compensating device, and wherein it is possible to switch between the first compensating current and the second compensating current.

30. The active sensor as claimed in claim 24, wherein the current sensing device can provide at its output at least one first current and at least one second current which is less by a defined in each case mutually different scaling factor than the current sensed at the input, wherein it is possible to switch between the first current and the second current on the output side.

31. The active sensor as claimed in claim 21, wherein the interface module additionally has at least one second connectable and/or controllable current source which is connected to the first node on the input side and to the second node on the output side.

32. The active sensor as claimed in claim 24, wherein the interface module additionally has at least one first current driver element that is capable of being activated, which is connected to the first node on the input side and provides on the output side a first current at the input of an additional current source, the output of which is connected to the second node, and wherein the first current driver element can additionally generate on the output side a second current which is different by a defined scaling factor with respect to the first current, at least one output path connected to the second node.

33. The active sensor as claimed in claim 19, wherein the measuring module and the interface module are constructed as an integrated circuit.

34. The active sensor as claimed in claim 26, wherein the current sensing device, the compensating device, at least one current driver element, at least one additional connectable, controllable current source, or any combination thereof, are connected to at least one signal output of the measuring module on the input side and are controlled by the measuring module, with regard to a switching-over of the scaling factors.

35. The use of at least one active sensor as claimed in claim 19 as a wheel speed sensor in a motor vehicle.

36. A method for compensating for amplitude fluctuations in output current signals of an active sensor which comprises a measuring module and an interface module including at least one first current source, an input line and an output line, said method comprising the steps of:
supplying energy to the active sensor by the input line and the output line;
generating output signals of the active sensor in the form of current signals at least by the first current source,
sensing a load current of the measuring module by a current sensing device and at least one compensating device,
generating at least one compensating current that is dependent upon the sensed load current of the measuring module; and
superimposing the compensating current on an uncorrected output current signal of the active sensor.

37. The method as claimed in claim 36, wherein the compensating device can generate at least one additional and/or alternative compensating current, wherein switching is effected between the compensating currents in dependence on at least one output signal of the measuring module.

38. The method as claimed in claim 36, wherein the interface module has at least one additional current source, at least one current driver element, or both at least one additional current source and at least one current driver element, which generates at least one output current which can be connected or switched in dependence on at least one output signal of the measuring module and which is superimposed on the output current of the active sensor.
